(19) United States
(12) Patent Application Publication
(10) Pub. No.: US 2023/0179178 A1
(43) Pub. Date: Jun. 8, 2023

(54) SYNTHETIC INDUCTIVE RESONANT DRIVE CIRCUIT

(71) Applicant: Microsoft Technology Licensing, LLC, Redmond, WA (US)

(72) Inventors: Chang Joon PARK, Sunnyvale, CA (US); Martin Francis GALINSKI, III, Mountain View, CA (US)

(73) Assignee: Microsoft Technology Licensing, LLC, Redmond, WA (US)

(21) Appl. No.: 17/457,418

(22) Filed: Dec. 2, 2021

(51) Int. Cl. H03H 11/42; G02C 11/00

(52) U.S. Cl. CPC H03H 11/42; G02C 11/10

(57) ABSTRACT

A resonant drive circuit for a capacitive sensor device includes a resonant LC stage, a signal source, and an amplifier stage. The resonant LC stage includes an inductorless floating gyrator circuit electrically connected to a sense capacitor. The inductorless floating gyrator circuit is configured to synthesize a fixed inductance. The resonant LC stage is configured to output a sensed capacitance signal based on the fixed inductance and a change in capacitance of the sense capacitor. The signal source is configured to output a reference signal. The amplifier stage is configured to receive the sensed capacitance signal and the reference signal and output a measured capacitance signal that indicates a difference in one or more of amplitude and phase between the sensed capacitance signal and the reference signal.

### BACKGROUND

Lower power consumption and smaller form factor designs are desirable in mixed reality (MR), augmented reality (AR), and virtual reality (VR) devices for longer battery life, portability, and comfort. A resonant drive circuit may be desirable for driving electronic components in such devices, because they employ low power drive signals that are boosted at a resonant frequency, which can reduce overall power consumption relative to non-resonant drive mechanisms.

### SUMMARY

A resonant drive circuit for a capacitive sensor device includes a resonant LC stage, a signal source, and an amplifier stage. The resonant LC stage includes an inductorless floating gyrator circuit electrically connected to a sense capacitor. The inductorless floating gyrator circuit is configured to synthesize a fixed inductance. The resonant LC stage is configured to output a sensed capacitance signal based on the fixed inductance and a change in capacitance of the sense capacitor. The signal source is configured to output a reference signal. The amplifier stage is configured to receive the sensed capacitance signal and the reference signal and output a measured capacitance signal that indicates a difference in one or more of amplitude and phase between the sensed capacitance signal and the reference signal.

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter. Furthermore, the claimed subject matter is not limited to implementations that solve any or all disadvantages noted in any part of this disclosure.

### BRIEF DESCRIPTION OF THE DRAWINGS

FIG. 1 shows an example near-eye display device including an example synthetic inductive resonant drive circuit for a capacitive sensor device.

FIG. 2 shows a block diagram of an example wearable device including a synthetic inductive resonant drive circuit for a capacitive sensor device.

FIG. 3 shows a circuit diagram of an example synthetic inductive resonant drive circuit for a capacitive sensor device.

FIG. 4 shows a graph of an alternating-current (AC) response of an example synthetic inductive resonant drive circuit.

FIG. 5 shows an example computing system.

### DETAILED DESCRIPTION

A resonant drive circuit may be used to drive various electronic components in mixed reality (MR), augmented reality (AR), and virtual reality (VR) devices. In one example, an inductor-capacitor (LC) resonant drive circuit includes a physical inductor to provide an inductance (L) for the LC resonant drive circuit. However, such a physical inductor has a large form factor and is bulky, which may make it difficult to integrate into a form factor design of such an MR/AR/VR device. Further, such a physical inductor may react to external magnetic fields and permeable materials that can cause electromagnetic interference (EMI) issues with operation of such an MR/AR/VR device.

Accordingly, the present description is directed to a resonant drive circuit for a capacitive sensor device that may be employed in a MR/AR/VR device. The resonant drive circuit synthesizes an inductance of a physical inductor with an arrangement of electronic components that are smaller and less bulky than the physical inductor. In one example, such an arrangement of electronic components includes resistors, capacitors, and operational amplifiers. Such an arrangement may be referred to herein as an inductorless floating gyrator circuit. The inductorless floating gyrator circuit is configured to invert the current—voltage characteristic of an electrical component, such as a capacitive circuit to make it behave inductively. Further, the inductorless floating gyrator circuit is referred to as being “floating,” because neither of the connecting nodes of the circuit is electrically connected to a ground node. The inductorless floating gyrator circuit replaces the physical inductor in the resonant drive circuit, and its components are selected and configured so as to provide the same impedance as the physical inductor. The inductorless floating gyrator circuit does not have the energy storage properties of a physical inductor. However, the lack of such energy storage properties is immaterial in this case, because such a resonant drive circuit does not actually use the inductor, or in this case the equivalent inductorless floating gyrator circuit, as an energy storage element.

By replacing the physical inductor with the inductorless floating gyrator circuit in the resonant drive circuit, the resonant drive circuit enables reductions in size, weight, and cost. Further, the inductorless floating gyrator circuit does not react to external magnetic fields and permeable materials like a physical inductor, and thus the inductorless floating gyrator circuit does not cause EMI issues.

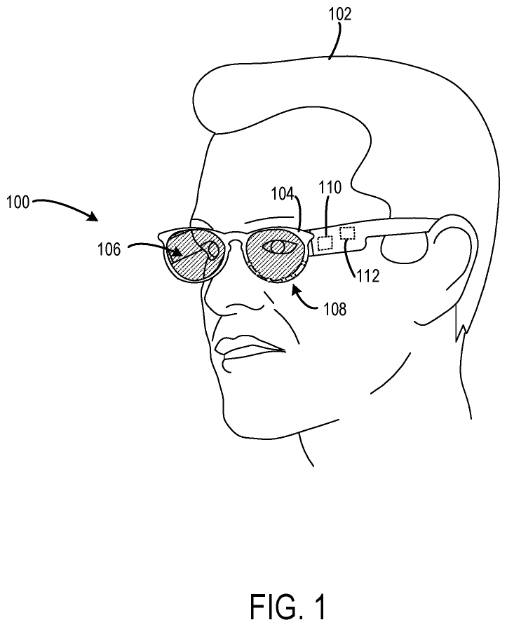

FIG. 1 shows an example near-eye display device 100 worn by a user 102. The near-eye display device 100 includes a frame 104 configured to hold a display 106 in a field of view of the user 102. In some implementations, the display 106 may be at least partially see-through, such as in the case of a MR/AR device. In other implementations, the display 106 may be opaque, such as in the case of a VR device.

A plurality of sense capacitors 108 are physically coupled to the frame 104. In one example, the plurality of sense capacitors 108 are embodied as a plurality of antennas. The plurality of sense capacitors 108 are configured to sense facial gestures based on movements of different parts of the user's face. For example, such facial gestures may include eye blinks, eye winks, smiles, frowns, and other facial gestures.

A resonant drive circuit 110 is electrically connected to the plurality of sense capacitors 108. The resonant drive circuit 110 includes an inductorless floating gyrator circuit that is configured to synthesize a fixed inductance in place of a physical inductor. The resonant drive circuit 110 is configured to measure capacitances of the plurality of sense capacitors 108 based on the fixed inductance synthesized by the inductorless floating gyrator circuit. The resonant drive circuit 110 is configured to output a measured capacitance signal to a microcontroller 112. The measured capacitance signal indicates measured capacitances of each of the plurality of sense capacitors 108. The microcontroller 112 is configured to recognize facial gestures performed by the user based on the measured capacitance signal and control operation of the near-eye display device 100 based on such recognized facial gestures.

In the illustrated implementation, the resonant drive circuit 110 and the microcontroller 112 are positioned on or within a portion of the frame 104 that extends over the user's ear. Such positioning of these electronic hardware components is provided as a non-limiting example. The resonant drive circuit 110 and the microcontroller 112 may be positioned on any suitable portion of the near-eye display device 100. In some implementations, the resonant drive circuit 110 and the microcontroller 112 optionally may be incorporated into a common electronic hardware module that is positioned on or within the frame 104.

The near-eye display device 100 is provided as a non-limiting example of a display device including a synthetic inductive resonant drive circuit for a capacitive sensor device. The disclosed examples of synthetic inductive resonant drive circuits may be implemented in any suitable type of display device, wearable device, or other type of electronic device.

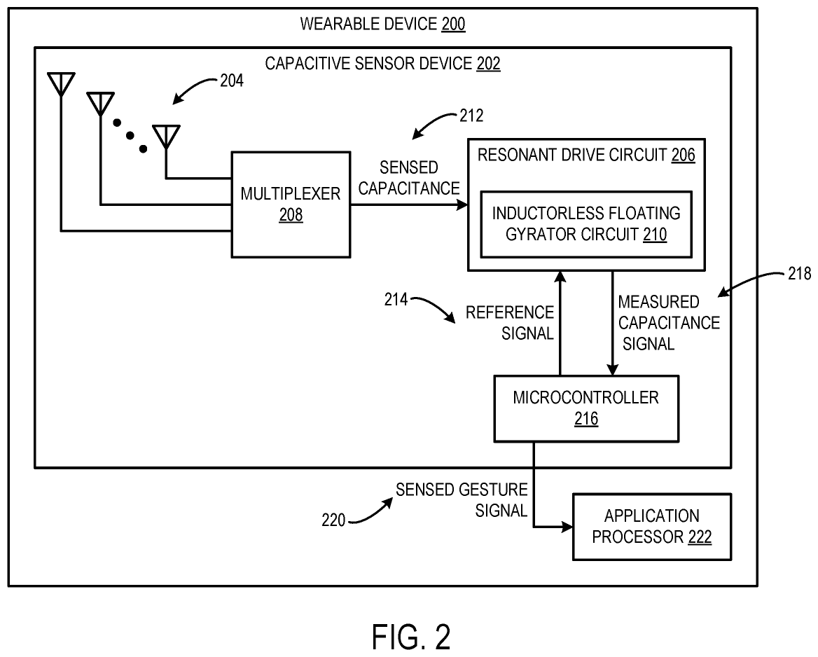

FIG. 2 shows a block diagram of an example wearable device 200 including a capacitive sensor device 202. In one example, the wearable device 200 represents the near-eye display device 100 shown in FIG. 1. The capacitive sensor device 202 may be configured to measure capacitances to facilitate any suitable function of the wearable device 200. The capacitive sensor device 202 includes a plurality of sense capacitors 204 in the form of antennas. Each of the plurality of sense capacitors 204 may be selectively electrically connected to a resonant drive circuit 206 via a multiplexer 208.

When a sense capacitor is electrically connected to the resonant drive circuit 206 via the multiplexer 208, the resonant drive circuit 206 is configured to receive a sensed capacitance 212 of the sense capacitor. The resonant drive circuit 206 includes an inductorless floating gyrator circuit 210 that is configured to synthesize a fixed inductance. This means the floating gyrator circuit 210 does not include an actual physical inductor and instead an arrangement of other electronic components is configured to provide the fixed inductance that is used for capacitive sensing. The inductorless floating gyrator circuit 210 is configured to output a sensed capacitance based on the fixed inductance and a change in the sensed capacitance 212 of the sense capacitor. The resonant drive circuit 206 is configured to receive a reference signal 214 from a signal source in the form of a microcontroller 216 of the capacitive sensor device 202. The resonant drive circuit 216 is configured to output a measured capacitance signal 218 to the microcontroller 216. The measured capacitance signal 218 indicates a difference in one or more of amplitude and phase between the sensed capacitance signal 212 and the reference signal 214. In some examples, the measured capacitance signal 218 indicates differences in both amplitude and phase between the sensed capacitance signal 212 and the reference signal 214. Further, the measured capacitance signal 218 may indicate the measured capacitances of each of the plurality of sense capacitors 204 over time as each one is selectively electrically connected to the resonant drive circuit 206.

The microcontroller 216 is configured to output a sensed gesture signal 220 to an application processor 222. The sensed gesture signal 220 may indicate one or more gestures recognized by the microcontroller 216 based on the measured capacitances of the plurality of sense capacitors 204. Returning to the example of the near-eye display device 100 shown in FIG. 1., the one or more sensed gestures may include one or more facial gestures sensed by the plurality of sense capacitors 108 arranged on the frame 104 of the near-eye display device 100. The application processor 222 may be configured to perform any suitable operation based on the sensed gesture signal 220. In one example, the application processor 222 may be configured to adjust presentation of a display based on a sensed gestured signal. In some implementations, at least some of the functionality of the microcontroller 216 may be performed by the application processor 222 or vice versa.

The wearable device 200 is provided as a non-limiting example of an electronic device including a capacitive sensor device that employs a synthetic inductive resonant drive circuit. The synthetic inductive resonant drive circuit may be employed in any suitable electronic device to synthesize an inductance for a capacitive sensor device or to provide some other function.

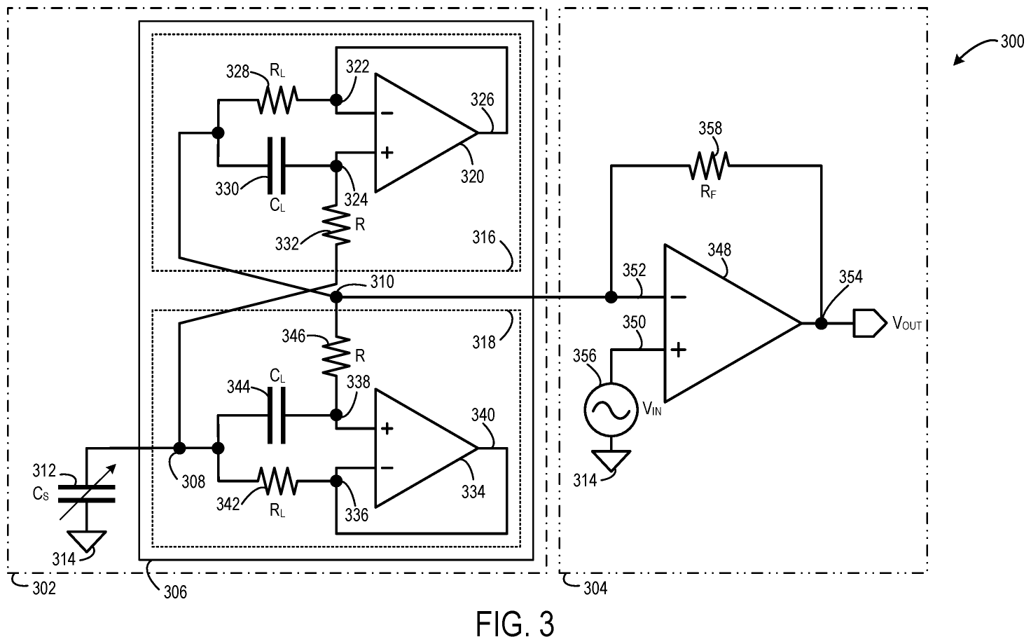

FIG. 3 shows a circuit diagram of an example synthetic inductive resonant drive circuit 300 for a capacitive sensor device, such as the capacitive sensor device 202 shown in FIG. 2. The resonant drive circuit 300 includes a resonant LC stage 302 electrically connected to an amplifier stage 304.

The resonant LC stage 302 includes an inductorless floating gyrator circuit 306. In one example, the inductorless floating gyrator circuit 306 represents the inductorless floating gyrator circuit 210 shown in FIG. 2. The inductorless floating gyrator circuit 306 includes an input node 308 and an output node 310. The input node 308 is electrically connected to a sense capacitor 312.

The sense capacitor 312 is electrically connected between the input node 308 and a ground nod 314. The ground node 314 may be set to any suitable reference voltage. In one example, the reference voltage of the ground node is set to zero volts.

The sense capacitor 312 has a capacitance (Cs) that varies based on the sense capacitor 312 capacitively coupling with a foreign medium (e.g., portions of a user's face). Returning to the example shown in FIG. 2, the sense capacitor 312 may represent one of the plurality of antennas that is selectively electrically connected to the resonant drive circuit 206 via the multiplexer 208 to measure the capacitance of the selected antenna. In other examples, the sense capacitor 312 may take another form.

The inductorless floating gyrator circuit 306 is configured to synthesize a fixed inductance, so that the resonant drive circuit 300 can be implemented without a physical inductor. The inductorless floating gyrator circuit 306 includes two mirrored inverting operational amplifier sub-stages 316 and 318. The first sub-stage 316 includes a first inverting operational amplifier 320 including a first inverting input terminal 322, a first non-inverting input terminal 324, and a first output terminal 326. The first output terminal is electrically connected to the first inverting input terminal 322. A first R_{L} resistor 328 is electrically connected between the output node 310 of the inductorless floating gyrator circuit 306 and the first inverting input terminal 322 of the first inverting operational amplifier 320. The first R_{L} resistor 328 has a resistance (R_{L}). A first C_{L} capacitor 330 is electrically connected between the output node 310 of the inductorless floating gyrator circuit 306 and the first non-inverting input terminal 324 of the first inverting operational amplifier 320. A first R resistor 332 is electrically connected between the first non-inverting input terminal 324 of the first inverting operational amplifier 320 and the input node 308 of the inductorless floating gyrator circuit 306.

The second sub-stage 318 includes a second inverting operational amplifier 334 including a second inverting input terminal 336, a second non-inverting input terminal 338, and a second output terminal 340. The second output terminal 340 is electrically connected to the second inverting input terminal 336. A second R_{L} resistor 342 is electrically connected between the input node 308 of the inductorless floating gyrator circuit 306 and the second inverting input terminal 336 of the second inverting operational amplifier 334. A second C_{L} capacitor 344 is electrically connected between the input node 308 of the inductorless floating gyrator circuit 306 and the second non-inverting input terminal 338 of the second inverting operational amplifier 334. A second R resistor 346 is electrically connected between the second non-inverting input terminal 338 of the second inverting operational amplifier 334 and the output node 310 of the inductorless floating gyrator circuit 306.

Each of the sub-stages 316 and 318 of the inductorless floating gyrator circuit 306 is configured to invert and multiply the effect of the capacitor C_{L} in an RC differentiating circuit configuration where the voltage across the resistor R behaves through time in the same manner as the voltage across an inductor. The respective inverting operational amplifiers 320, 334 buffers the voltage and applies the voltage back to the input through the resistor R_{L}. The resulting effect is an impedance of the form of an ideal inductor with a series resistance R_{L}. In other words, the sub-stages 316 and 318 of the inductorless floating gyrator circuit 306 collectively have an impedance that is equal to that of a physical inductor having an inductance equal to the fixed inductance synthesized by the inductorless floating gyrator circuit 306. In one example, the impedance of the inductorless floating gyrator circuit 306 is

$${Z}_{e q} = \frac{{R}_{L} + s {R}_{L} R {C}_{L}}{1 + ( s {R}_{L} {C}_{L} )} ,$$

which is equivalent to the impedance of the physical inductor. The value of the resistors and capacitors in the inductorless floating gyrator circuit 306 may be optimized based on the target resonant frequency of the resonant drive circuit 300 and the baseline capacitance of the sense capacitor 312.

The resonant LC stage 302 has a resonant frequency that is based on the fixed inductance generated by the inductorless floating gyrator circuit 306 and a baseline capacitance of the sense capacitor 312. As used herein, the baseline capacitance is the capacitance of the sense capacitor 312 when the sense capacitor 312 is not capacitively coupled with a foreign medium or otherwise transferring energy to a foreign medium. The inductorless floating gyrator circuit 306 is referred to as being “floating,” because neither of the input node 308 nor the output node 310 is electrically connected to the ground node 314. Such an arrangement causes the resonant LC stage 302 to operate as a bandpass filter having a bandpass region that is aligned with the resonant frequency of the resonant LC stage 302. The resonant LC stage 302 is configured to output a sensed capacitance signal at the output node 310 based on the fixed inductance and a change in capacitance of the sense capacitor 312. The resonant LC stage 302 operates in such a manner without the uses of a physical inductor, because the inductorless floating gyrator circuit 306 synthesizes the fixed inductance for the resonant LC stage 302 instead.

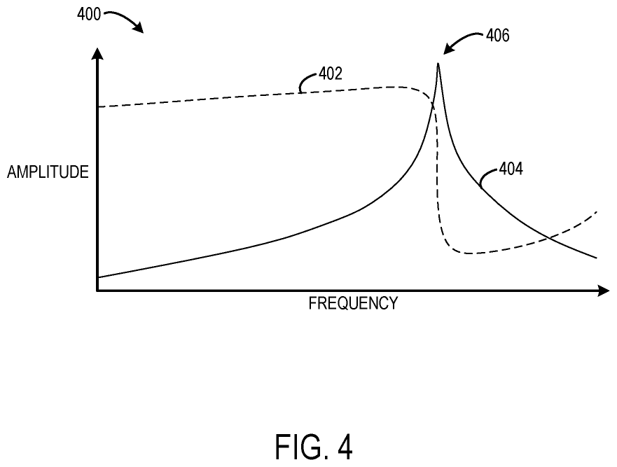

Turning to FIG. 4, a graph 400 shows an AC response of the synthetic inductive resonant drive circuit 300. The graph 400 plots frequency vs amplitude. A phase curve 402 indicates a phase of the AC response of the synthetic inductive resonant drive circuit 300. A gain curve 404 indicates a gain of the AC response of the synthetic inductive resonant drive circuit 300. Note that a very large output signal can be achieved with small input signal due to the peak gain 406 at the resonant frequency. Therefore, the required output signal amplitude can be achieved with smaller inductance (L) and capacitance (C) values of the electronic components in the of the synthetic inductive resonant drive circuit 300, in some implementations.

Returning to FIG. 3, the amplifier stage 304 includes an inverting operational amplifier 348. The inverting operational amplifier 348 includes a non-inverting input terminal 350, an inverting input terminal 352, and an output terminal 354. The inverting input terminal 352 is electrically connected to the output node 310 of the inductorless floating gyrator circuit 306. The non-inverting input terminal 350 is electrically connected to a signal source 356. A feedback resistor 358 is electrically connected between the inverting input terminal 352 and the output terminal 354 of the inverting operational amplifier 348. In some implementations, the operational amplifier 348 may have a wide gain bandwidth (GBW) to avoid any extra group delay and enough output current to provide driving capability.

The signal source 356 is configured to output a reference signal (e.g., the reference signal 214 shown in FIG. 2). In some examples, the reference signal may have a fixed frequency that is equal to the resonant frequency of the resonant LC stage 302. The signal source 356 is electrically connected between the non-inverting input terminal 350 of an inverting operational amplifier 348 of the amplifier state 304 and the ground node 314. In the illustrated example, the signal source 356 is configured to output a sinusoidal signal. In other examples, the signal source 356 may output a different type of reference signal.

The inverting operational amplifier 348 is configured to receive the sensed capacitance signal from the output node 310 of the resonant LC stage 302 through the inverting input terminal 352. The inverting operational amplifier 348 is configured to receive the reference signal from the signal source 356 through the non-inverting input terminal 350. The inverting operational amplifier 348 is configured to output a measured capacitance signal (e.g., the measured capacitance signal 218 shown in FIG. 2) to the output terminal 354. The measured capacitance signal indicates a difference in one or more of amplitude and phase between the sensed capacitance signal and the reference signal. In some examples, the measured capacitance signal 218 indicates differences in both amplitude and phase between the sensed capacitance signal 212 and the reference signal 214.

By replacing a physical inductor with the inductorless floating gyrator circuit 306 in the resonant drive circuit 300, a size, weight, and cost of the resonant drive circuit 300 can be reduced relative to a resonant drive circuit that includes a physical inductor. In some implementations, such a configuration allows for the resonant drive circuit to be implemented as an application-specific integrated circuit (ASIC). Such an ASIC chip may have a reduced Z-height constraint relative to a physical inductor that allows for the ASIC chip to be more easily incorporated into a form factor design of a mobile device, such as the near-eye display device 100 shown in FIG. 1. Further, the inductorless floating gyrator circuit does not react to external magnetic fields and permeable materials like a physical inductor, and thus the inductorless floating gyrator circuit does not cause EMI issues.

Although the resonant drive circuit is discussed herein in the context of being used with a capacitive sensor device, the concepts discussed herein are broadly applicable to any suitable electronic device.

In some implementations, the methods and processes described herein may be tied to a computing system of one or more computing devices. In particular, such methods and processes may be implemented as computer hardware, a computer-application program or service, an application-programming interface (API), a library, and/or other computer-program product.

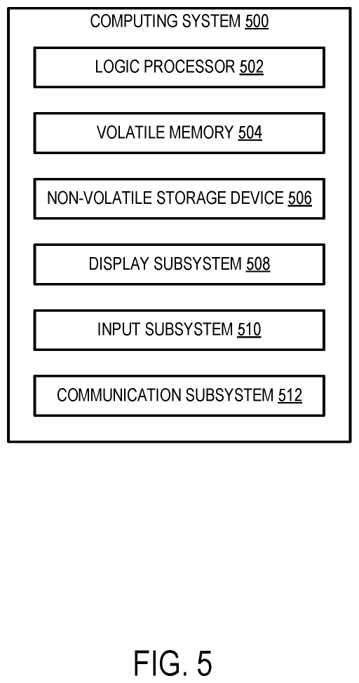

FIG. 5 schematically shows a non-limiting implementation of a computing system 500 that can enact one or more of the methods and processes described above. Computing system 500 is shown in simplified form. Computing system 500 may embody the near-eye display device 100 shown in FIG. 1, the wearable device 200 shown in FIG. 2, and any other suitable device that include the resonant drive circuit 300 shown in FIG. 3 and described herein. Computing system 500 may take the form of one personal computers, server computers, tablet computers, home-entertainment computers, network computing devices, gaming devices, mobile computing devices, mobile communication devices (e.g., smart phone), and/or other computing devices, and wearable computing devices such as head-mounted, near-eye augmented/mixed/virtual reality devices.

Computing system 500 includes a logic processor 502, volatile memory 504, and a non-volatile storage device 506. Computing system 500 may optionally include a display subsystem 508, input subsystem 510, communication subsystem 512, and/or other components not shown in FIG. 5.

Logic processor 502 includes one or more physical devices configured to execute instructions. For example, the logic processor may be configured to execute instructions that are part of one or more applications, programs, routines, libraries, objects, components, data structures, or other logical constructs. Such instructions may be implemented to perform a task, implement a data type, transform the state of one or more components, achieve a technical effect, or otherwise arrive at a desired result.

The logic processor 502 may include one or more physical processors (hardware) configured to execute software instructions. Additionally or alternatively, the logic processor may include one or more hardware logic circuits or firmware devices configured to execute hardware-implemented logic or firmware instructions. Processors of the logic processor 502 may be single-core or multi-core, and the instructions executed thereon may be configured for sequential, parallel, and/or distributed processing. Individual components of the logic processor optionally may be distributed among two or more separate devices, which may be remotely located and/or configured for coordinated processing. Aspects of the logic processor may be virtualized and executed by remotely accessible, networked computing devices configured in a cloud-computing configuration. In such a case, these virtualized aspects are run on different physical logic processors of various different machines, it will be understood.

Non-volatile storage device 506 includes one or more physical devices configured to hold instructions executable by the logic processors to implement the methods and processes described herein. When such methods and processes are implemented, the state of non-volatile storage device 506 may be transformed—e.g., to hold different data.

Non-volatile storage device 506 may include physical devices that are removable and/or built-in. Non-volatile storage device 506 may include optical memory (e.g., CD, DVD, HD-DVD, Blu-Ray Disc, etc.), semiconductor memory (e.g., ROM, EPROM, EEPROM, FLASH memory, etc.), and/or magnetic memory (e.g., hard-disk drive, floppy-disk drive, tape drive, MRAM, etc.), or other mass storage device technology. Non-volatile storage device 506 may include nonvolatile, dynamic, static, read/write, read-only, sequential-access, location-addressable, file-addressable, and/or content-addressable devices. It will be appreciated that non-volatile storage device 506 is configured to hold instructions even when power is cut to the non-volatile storage device 506.

Volatile memory 504 may include physical devices that include random access memory. Volatile memory 504 is typically utilized by logic processor 502 to temporarily store information during processing of software instructions. It will be appreciated that volatile memory 504 typically does not continue to store instructions when power is cut to the volatile memory 504.

Aspects of logic processor 502, volatile memory 504, and non-volatile storage device 506 may be integrated together into one or more hardware-logic components. Such hardware-logic components may include field-programmable gate arrays (FPGAs), program- and application-specific integrated circuits (PASIC/ASICs), program- and application-specific standard products (PSSP/ASSPs), system-on-a-chip (SOC), and complex programmable logic devices (CPLDs), for example.

When included, display subsystem 508 may be used to present a visual representation of data held by non-volatile storage device 506. The visual representation may take the form of a graphical user interface (GUI). As the herein described methods and processes change the data held by the non-volatile storage device, and thus transform the state of the non-volatile storage device, the state of display subsystem 508 may likewise be transformed to visually represent changes in the underlying data. Display subsystem 508 may include one or more display devices utilizing virtually any type of technology. Such display devices may be combined with logic processor 502, volatile memory 504, and/or non-volatile storage device 506 in a shared enclosure, or such display devices may be peripheral display devices.

When included, input subsystem 510 may comprise or interface with one or more user-input devices such as a keyboard, mouse, touch screen, microphone for speech and/or voice recognition, a camera (e.g., a webcam), or game controller.

When included, communication subsystem 512 may be configured to communicatively couple various computing devices described herein with each other, and with other devices. Communication subsystem 512 may include wired and/or wireless communication devices compatible with one or more different communication protocols. As non-limiting examples, the communication subsystem may be configured for communication via a wireless telephone network, or a wired or wireless local- or wide-area network, such as a HDMI over Wi-Fi connection. In some implementations, the communication subsystem may allow computing system 500 to send and/or receive messages to and/or from other devices via a network such as the Internet.

In an example, a resonant drive circuit for a capacitive sensor device comprises a resonant LC stage including an inductorless floating gyrator circuit including an input node and an output node, the input node electrically connected to a sense capacitor, the inductorless floating gyrator circuit being configured to synthesize a fixed inductance, the resonant LC stage being configured to output a sensed capacitance signal based on the fixed inductance and a change in capacitance of the sense capacitor, a signal source configured to output a reference signal, and an amplifier stage configured to receive the sensed capacitance signal from the output node of the resonant LC stage and the reference signal from the signal source and output a measured capacitance signal that indicates a difference in one or more of amplitude and phase between the sensed capacitance signal and the reference signal. In this example and/or other examples, the inductorless floating gyrator circuit may include two mirrored inverting operational amplifier sub-stages. In this example and/or other examples, a first sub-stage of the two mirrored inverting operational amplifier sub-stages may include a first inverting operational amplifier including a first inverting input terminal, a first non-inverting input terminal, and a first output terminal electrically connected to the first inverting input terminal, a first R_{L} resistor electrically connected between the output node of the inductorless floating gyrator circuit and the first inverting input terminal of the first inverting operational amplifier, a first C_{L} capacitor electrically connected between the output node of the inductorless floating gyrator circuit and the first non-inverting input terminal of the first inverting operational amplifier, and a first R resistor electrically connected between the first non-inverting input terminal of the first inverting operational amplifier and the input node of the inductorless floating gyrator circuit. In this example and/or other examples, a second sub-stage of the two mirrored inverting operational amplifier sub-stages may include a second inverting operational amplifier including a second inverting input terminal, a second non-inverting input terminal, and a second output terminal electrically connected to the second inverting input terminal, a second R_{L} resistor electrically connected between the input node of the inductorless floating gyrator circuit and the second inverting input terminal of the second inverting operational amplifier, a second C_{L} capacitor electrically connected between the input node of the inductorless floating gyrator circuit and the second non-inverting input terminal of the second inverting operational amplifier, and a second R resistor electrically connected between the second non-inverting input terminal of the second inverting operational amplifier and the output node of the inductorless floating gyrator circuit. In this example and/or other examples, the amplifier stage may include an inverting operational amplifier. In this example and/or other examples, the inverting operational amplifier may include an inverting input terminal electrically connected to the output node of the inductorless floating gyrator circuit, a non-inverting input terminal electrically connected to the signal source, and an output terminal configured to output the measured capacitance signal. In this example and/or other examples, the amplifier stage may include a feedback resistor electrically connected between the inverting input terminal and the output terminal of the operational amplifier. In this example and/or other examples, the sense capacitor may be one of a plurality of sense capacitors selectively electrically connected to the resonant drive circuit via a multiplexer, and the measured capacitance signal may indicate measured capacitances of each of the plurality of sense capacitors. In this example and/or other examples, the sense capacitor may be mounted on a frame of wearable device. In this example and/or other examples, the wearable device may be a near-eye display device, the sense capacitor may be positioned on the frame proximate to a user's face when the near-eye display device is worn by a user, and the near-eye display device may be configured to identify facial gestures based on the measured capacitance signal output from the capacitive sensor device. In this example and/or other examples, the inductorless floating gyrator circuit may be configured to have an impedance that is equal to that of a physical inductor having an inductance equal to the fixed inductance synthesized by the inductorless floating gyrator circuit. In this example and/or other examples, the resonant drive circuit may be implemented as an application-specific integrated circuit (ASIC).

In another example, a wearable device, comprises a frame, and a capacitive sensor device including a sense capacitor physically coupled to the frame and a resonant drive circuit including a resonant LC stage including an inductorless floating gyrator circuit including an input node and an output node, the input node electrically connected to the sense capacitor, the inductorless floating gyrator circuit being configured to synthesize a fixed inductance, the resonant LC stage being configured to output a sensed capacitance signal based on the fixed inductance and a change in capacitance of the sense capacitor, a signal source configured to output a reference signal, and an amplifier stage configured to receive the sensed capacitance signal from the output node of the resonant LC stage and the reference signal from the signal source and output a measured capacitance signal that indicates a difference in one or more of amplitude and phase between the sensed capacitance signal and the reference signal. In this example and/or other examples, the sense capacitor may be one of a plurality of sense capacitors physically coupled to the frame and selectively electrically connected to the resonant drive circuit via a multiplexer, and the measured capacitance signal may indicate measured capacitances of each of the plurality of sense capacitors. In this example and/or other examples, the wearable device may be a near-eye display device, the sense capacitor may be positioned on the frame proximate to a user's face when the near-eye display device is worn by a user, and the near-eye display device may be configured to identify facial gestures based on the measured capacitance signal output from the capacitive sensor device. In this example and/or other examples, the inductorless floating gyrator circuit may include two mirrored inverting operational amplifier sub-stages. In this example and/or other examples, a first sub-stage of the two mirrored inverting operational amplifier sub-stages may include a first inverting operational amplifier including a first inverting input terminal, a first non-inverting input terminal, and a first output terminal electrically connected to the first inverting input terminal, a first R_{L} resistor electrically connected between the output node of the inductorless floating gyrator circuit and the first inverting input terminal of the first inverting operational amplifier, a first C_{L} capacitor electrically connected between the output node of the inductorless floating gyrator circuit and the first non-inverting input terminal of the first inverting operational amplifier, and a first R resistor electrically connected between the first non-inverting input terminal of the first inverting operational amplifier and the input node of the inductorless floating gyrator circuit. In this example and/or other examples, the second sub-stage of the two mirrored inverting operational amplifier sub-stages may include a second inverting operational amplifier including a second inverting input terminal, a second non-inverting input terminal, and a second output terminal electrically connected to the second inverting input terminal, a second R_{L} resistor electrically connected between the input node of the inductorless floating gyrator circuit and the second inverting input terminal of the second inverting operational amplifier, a second CL capacitor electrically connected between the input node of the inductorless floating gyrator circuit and the second non-inverting input terminal of the second inverting operational amplifier, and a second R resistor electrically connected between the second non-inverting input terminal of the second inverting operational amplifier and the output node of the inductorless floating gyrator circuit. In this example and/or other examples, the inductorless floating gyrator circuit may be configured to have an impedance that is equal to that of a physical inductor having an inductance equal to the fixed inductance synthesized by the inductorless floating gyrator circuit.

In yet another example, a near-eye display device, comprises a frame wearable on a user's face, and a capacitive sensor device including a sense capacitor and a resonant drive circuit, the sense capacitor being physically coupled to the frame proximate to the user's face when the near-eye display device is worn by a user, and the resonant drive circuit including a resonant LC stage including an inductorless floating gyrator circuit including an input node and an output node, the input node electrically connected to the sense capacitor, the inductorless floating gyrator circuit being configured to synthesize a fixed inductance, the resonant LC stage being configured to output a sensed capacitance signal based on the fixed inductance and a change in capacitance of the sense capacitor, a signal source configured to output a reference signal, and an amplifier stage configured to receive the sensed capacitance signal from the output node of the resonant LC stage and the reference signal from the signal source and output a measured capacitance signal that indicates a difference in one or more of amplitude and phase between the sensed capacitance signal and the reference signal, wherein the near-eye display device is configured to identify facial gestures based on the measured capacitance signal output from the capacitive sensor device.

It will be understood that the configurations and/or approaches described herein are exemplary in nature, and that these specific embodiments or examples are not to be considered in a limiting sense, because numerous variations are possible. The specific routines or methods described herein may represent one or more of any number of processing strategies. As such, various acts illustrated and/or described may be performed in the sequence illustrated and/or described, in other sequences, in parallel, or omitted. Likewise, the order of the above-described processes may be changed.

The subject matter of the present disclosure includes all novel and non-obvious combinations and sub-combinations of the various processes, systems and configurations, and other features, functions, acts, and/or properties disclosed herein, as well as any and all equivalents thereof.

1. A resonant drive circuit for a capacitive sensor device, comprising:
a resonant LC stage including an inductorless floating gyrator circuit including an input node and an output node, the input node electrically connected to a sense capacitor, the inductorless floating gyrator circuit being configured to synthesize a fixed inductance, the resonant LC stage being configured to output a sensed capacitance signal based on the fixed inductance and a change in capacitance of the sense capacitor;
a signal source configured to output a reference signal; and
an amplifier stage configured to receive the sensed capacitance signal from the output node of the resonant LC stage and the reference signal from the signal source and output a measured capacitance signal that indicates a difference in one or more of amplitude and phase between the sensed capacitance signal and the reference signal.

2. The resonant drive circuit of claim 1, wherein the inductorless floating gyrator circuit includes two mirrored inverting operational amplifier sub-stages.

3. The resonant drive circuit of claim 2, wherein a first sub-stage of the two mirrored inverting operational amplifier sub-stages includes:
a first inverting operational amplifier including a first inverting input terminal, a first non-inverting input terminal, and a first output terminal electrically connected to the first inverting input terminal,
a first R_{L} resistor electrically connected between the output node of the inductorless floating gyrator circuit and the first inverting input terminal of the first inverting operational amplifier,
a first C_{L} capacitor electrically connected between the output node of the inductorless floating gyrator circuit and the first non-inverting input terminal of the first inverting operational amplifier, and
a first R resistor electrically connected between the first non-inverting input terminal of the first inverting operational amplifier and the input node of the inductorless floating gyrator circuit.

4. The resonant drive circuit of claim 3, wherein a second sub-stage of the two mirrored inverting operational amplifier sub-stages includes:
a second inverting operational amplifier including a second inverting input terminal, a second non-inverting input terminal, and a second output terminal electrically connected to the second inverting input terminal,
a second R_{L} resistor electrically connected between the input node of the inductorless floating gyrator circuit and the second inverting input terminal of the second inverting operational amplifier,
a second C_{L} capacitor electrically connected between the input node of the inductorless floating gyrator circuit and the second non-inverting input terminal of the second inverting operational amplifier, and
a second R resistor electrically connected between the second non-inverting input terminal of the second inverting operational amplifier and the output node of the inductorless floating gyrator circuit.

5. The resonant drive circuit of claim 1, wherein the amplifier stage includes an inverting operational amplifier.

6. The resonant drive circuit of claim 5, wherein the inverting operational amplifier includes an inverting input terminal electrically connected to the output node of the inductorless floating gyrator circuit, a non-inverting input terminal electrically connected to the signal source, and an output terminal configured to output the measured capacitance signal.

7. The resonant drive circuit of claim 6, wherein the amplifier stage includes a feedback resistor electrically connected between the inverting input terminal and the output terminal of the operational amplifier.

8. The resonant drive circuit of claim 1, wherein the sense capacitor is one of a plurality of sense capacitors selectively electrically connected to the resonant drive circuit via a multiplexer, and wherein the measured capacitance signal indicates measured capacitances of each of the plurality of sense capacitors.

9. The resonant drive circuit of claim 1, wherein the sense capacitor is mounted on a frame of wearable device.

10. The resonant drive circuit of claim 8, wherein the wearable device is a near-eye display device, wherein the sense capacitor is positioned on the frame proximate to a user's face when the near-eye display device is worn by a user, and wherein the near-eye display device is configured to identify facial gestures based on the measured capacitance signal output from the capacitive sensor device.

11. The resonant drive circuit of claim 1, wherein the inductorless floating gyrator circuit is configured to have an impedance that is equal to that of a physical inductor having an inductance equal to the fixed inductance synthesized by the inductorless floating gyrator circuit.

12. The resonant drive circuit of claim 1, wherein the resonant drive circuit is implemented as an application-specific integrated circuit (ASIC).

13. A wearable device, comprising:
a frame; and
a capacitive sensor device including a sense capacitor physically coupled to the frame and a resonant drive circuit including:
a resonant LC stage including an inductorless floating gyrator circuit including an input node and an output node, the input node electrically connected to the sense capacitor, the inductorless floating gyrator circuit being configured to synthesize a fixed inductance, the resonant LC stage being configured to output a sensed capacitance signal based on the fixed inductance and a change in capacitance of the sense capacitor;
a signal source configured to output a reference signal; and
an amplifier stage configured to receive the sensed capacitance signal from the output node of the resonant LC stage and the reference signal from the signal source and output a measured capacitance signal that indicates a difference in one or more of amplitude and phase between the sensed capacitance signal and the reference signal.

14. The wearable device of claim 13, wherein the sense capacitor is one of a plurality of sense capacitors physically coupled to the frame and selectively electrically connected to the resonant drive circuit via a multiplexer, and wherein the measured capacitance signal indicates measured capacitances of each of the plurality of sense capacitors.

15. The wearable device of claim 13, wherein the wearable device is a near-eye display device, wherein the sense capacitor is positioned on the frame proximate to a user's face when the near-eye display device is worn by a user, and wherein the near-eye display device is configured to identify facial gestures based on the measured capacitance signal output from the capacitive sensor device.

16. The wearable device of claim 13, wherein the inductorless floating gyrator circuit includes two mirrored inverting operational amplifier sub-stages.

17. The wearable device of claim 16, wherein a first sub-stage of the two mirrored inverting operational amplifier sub-stages includes:
a first inverting operational amplifier including a first inverting input terminal, a first non-inverting input terminal, and a first output terminal electrically connected to the first inverting input terminal,
a first R_{L} resistor electrically connected between the output node of the inductorless floating gyrator circuit and the first inverting input terminal of the first inverting operational amplifier,
a first C_{L} capacitor electrically connected between the output node of the inductorless floating gyrator circuit and the first non-inverting input terminal of the first inverting operational amplifier, and
a first R resistor electrically connected between the first non-inverting input terminal of the first inverting operational amplifier and the input node of the inductorless floating gyrator circuit.

18. The wearable device of claim 17, wherein a second sub-stage of the two mirrored inverting operational amplifier sub-stages includes:
a second inverting operational amplifier including a second inverting input terminal, a second non-inverting input terminal, and a second output terminal electrically connected to the second inverting input terminal,
a second R_{L} resistor electrically connected between the input node of the inductorless floating gyrator circuit and the second inverting input terminal of the second inverting operational amplifier,
a second C_{L} capacitor electrically connected between the input node of the inductorless floating gyrator circuit and the second non-inverting input terminal of the second inverting operational amplifier, and
a second R resistor electrically connected between the second non-inverting input terminal of the second inverting operational amplifier and the output node of the inductorless floating gyrator circuit.

19. The wearable device of claim 13, wherein the inductorless floating gyrator circuit is configured to have an impedance that is equal to that of a physical inductor having an inductance equal to the fixed inductance synthesized by the inductorless floating gyrator circuit.

20. A near-eye display device, comprising:
a frame wearable on a user's face; and
a capacitive sensor device including a sense capacitor and a resonant drive circuit, the sense capacitor being physically coupled to the frame proximate to the user's face when the near-eye display device is worn by a user, and the resonant drive circuit including:
a resonant LC stage including an inductorless floating gyrator circuit including an input node and an output node, the input node electrically connected to the sense capacitor, the inductorless floating gyrator circuit being configured to synthesize a fixed inductance, the resonant LC stage being configured to output a sensed capacitance signal based on the fixed inductance and a change in capacitance of the sense capacitor;
a signal source configured to output a reference signal; and
an amplifier stage configured to receive the sensed capacitance signal from the output node of the resonant LC stage and the reference signal from the signal source and output a measured capacitance signal that indicates a difference in one or more of amplitude and phase between the sensed capacitance signal and the reference signal,
wherein the near-eye display device is configured to identify facial gestures based on the measured capacitance signal output from the capacitive sensor device.
